(19) United States
(12) Patent Application Publication
(10) Pub. No.: US 2010/0068529 A1
(43) Pub. Date: Mar. 18, 2010

(54) FILMS CONTAINING AN INFUSED OXYGENATED AS AND METHODS FOR THEIR PREPARATION

(76) Inventors: Matthew C. Asplund, Provo, UT (US); Robert C. Davis, Provo, UT (US); Douglas P. Hansen, Spanish Fork, UT (US); Matthew R. Linford, Orem, UT (US); Barry M. Lunt, Provo, UT (US)

Correspondence Address: Pepper/Millenniata, 50th Floor, 500 Grant Street, Pttsburgh, PA, 15219-2502, US

(21) Appl. No.: 12/473,250

(22) Filed: May 27, 2009

Related U.S. Application Data
(60) Provisional application No. 61/191,925, filed on Sep. 12, 2008.

(51) Int. Cl. B32B 27/36; B32B 17/06; C09D 1/00; C23C 14/34

(52) U.S. Cl. 428/412; 428/426; 106/286.8; 204/192.15

(57) ABSTRACT

Objects having a substrate and an oxygenated gas infused coating layer are disclosed. The coating layer provides enhanced physical durability, chemical resistance, optical transparency, and ablatability as compared to conventional coatings.

### CROSS REFERENCE TO RELATED APPLICATIONS

The present application claims priority to U.S. Provisional Patent Application Ser. No. 61/191,925 filed Sep. 12, 2008, the contents of which are incorporated herein by reference.

### FIELD OF THE INVENTION

The invention relates to carbon films and, more specifically, to carbon films activated with oxygenated gas.

### DESCRIPTION OF RELATED ART

Carbon films are used in a variety of commercially important applications. Carbon is attractive due to its low cost, corrosion resistance, relative chemical inertness, resistive properties, and ease of handling.

Carbon film resistors are commonly used in electronic devices. The resistors contain ceramic rods coated with a carbon film. The film is a composite of carbon powder and ceramic powder (typically alumina), mixed in varying proportions. The carbon film is “spiralled away” by machine in order to achieve a desired resistance across the rod. Metal leads and end caps are added, and the resistor is covered with an insulating coating. By varying the ratio of the carbon powder to the ceramic powder, and the degree of “spiraling”, different resistance values can be obtained.

Carbon films have also been used as a pattern mask for metal etching. For example, U.S. Pat. No. 6,939,808 (issued Sep. 6, 2005) suggests using a photoresist layer in combination with an amorphous carbon layer to pattern a metal layer.

Carbon films have also been used in probes for the detection and quantification of biological molecules. For example, carbon film resistor electrodes have been used as electrode transducers in biosensors for oxidase-based enzymes. (DeLuca, S. et al., Talanta, 68(2): 171-178 (1995)).

Carbon films have also been used in the preparation of thin-film electrodes by electron beam evaporation onto doped silicon (Blackstock, J. J. et al., Anal. Chem. 76(9): 2544-2552 (2004)). Thermal degradation of a polyvinylidene chloride and polyvinyl chloride copolymer has also been reported to make carbon film electrodes (U.S. Pat. No. 5,993,969; issued Nov. 30, 1999).

Carbon films have been reported to be a useful coating for steel and titanium alloys in aircraft landing gear, flap tracks, and other fatigue sensitive parts (Sundaram, V. S., Surface and Coatings Tech. 201 (6): 2707-2711 (2006)). Carbon was found to favorably replace hard chromium plating for these aircraft parts. The carbon films were found to confer improved wear and fatigue characteristics, and was more environmentally and workplace safety attractive.

Carbon films have also been described as coatings for eyeglasses. U.S. Pat. No. 5,125,808 (issued Aug. 4, 1992) and U.S. Pat. No. 5,268,217 (issued Dec. 7, 1993) discuss the use of a diamond-like carbon layer and an intermediate “interlayer” to coat a substrate. The Background of the Invention section mentions that diamond-like carbon coating will impart improved abrasion resistance to a substrate only if the adherence of the coating to the parent substrate is excellent. The Background further mentions that “[t]he most obvious and common approach to coating the glass substrate is to apply the DLC coating directly onto a clean glass surface. However, this approach often results in a DLC coating which displays poor adhesion and therefore, poor abrasion resistance. DLC coatings are typically under significant compressive stress”. The patent discusses the use of at least one interlayer between the DLC layer and the substrate in order to improve adhesion.

Films containing only carbon tend to be hard and brittle. To minimize cracking, additives have been used to modulate the physical properties of the films.

PCT Publication WO/2006/011279 (published Feb. 2, 2006) suggests the use of a hydrogen-containing carbon film to minimize peeling of the film from a substrate.

U.S. Pat. No. 4,647,947 (issued Mar. 3, 1987) describes a substrate and an electromagnetic energy-absorbing layer. The layer can contain low melting metals such as tellurium, antimony, tin, bismuth, zinc, or lead. The layer can also contain elements that are in a gaseous state at a temperature below a predetermined temperature. Application of energy causes the recording layer to be raised, forming a protuberance.

U.S. Pat. No. 5,045,165 (issued Sep. 3, 1991) offers sputtering of a carbon film in the presence of hydrogen onto a magnetic disk. The resulting film confers enhanced wear resistance.

U.S. Pat. No. 6,528,115 B1 (issued Mar. 4, 2003) offered a hard carbon thin film on a substrate. The film has a graded structure in which the ratio of SP² to SP³ carbon-carbon bonding in the film decreases in its thickness direction from the substrate interface towards the surface of the thin film. Argon, methane, and hydrogen gases are used in a vacuum chamber to produce the carbon thin film.

U.S. Pat. No. 6,753,042 B1 (issued Jun. 22, 2004) suggests applying a wear-resistant and low-friction hard amorphous, diamond like carbon coating directly onto the external surface of a magnetic recording media sensor. The coating was applied using vacuum pulse arc carbon sputtering and ion beam surface treatments.

U.S. Patent Publication No. 2007/0098993 A1 (published May 3, 2007) offers a multi-layered stacked diamond-like film. Each layer contains carbon, hydrogen, and a metal. The layers were prepared by a co-sputtering process using hydrogen gas, methane or ethane, and noble gas.

U.S. Patent Publication No. 2008/0053819 A1 (published Mar. 6, 2008) offers a carbon thin film for use as an electrode of a thin film electroluminescent device. The film was produced using a closed-field unbalanced magnetron sputtering process at low temperature. Sputtering was performed with argon gas, which allowed preparation of films lacking hydrogen. Hydrogen is described as conferring insulation properties to carbon films, and its incorporation is therefore to be avoided.

Despite the efforts made to date, there still exists a need for new carbon film materials that display enhanced or different properties relative to traditional carbon films.

### SUMMARY OF THE INVENTION

Carbon films containing at least one infused oxygenated gas exhibit improved durability and optical properties relative to carbon films lacking the oxygenated gas. By adjusting the concentration of gas, desired properties can be easily achieved.

### DESCRIPTION OF THE FIGURES

The following figures form part of the present specification and are included to further demonstrate certain aspects of the present invention. The invention may be better understood by reference to one or more of these figures in combination with the detailed description of specific embodiments presented herein.

FIG. 1 shows the decrease in optical density (or increase in optical transparency) of carbon films prepared with increasing concentrations of the oxygenated gas carbon dioxide. The x-axis is wavelengths in nm. The y-axis is absorbance per thickness (1/nm). The line indicated with square symbols represents 1% (v/v) carbon dioxide. The line indicated with diamond symbols represents 2% (v/v) carbon dioxide. The line indicated with round symbols represents 4% (v/v) carbon dioxide.

FIG. 2 shows a plot of transmission (y-axis) against wavelength (in nm, x-axis) for quartz (top, relatively flat plot) and quartz coated with an infused carbon layer (bottom, sloped plot).

### DETAILED DESCRIPTION OF THE INVENTION

While compositions and methods are described in terms of “comprising” various components or steps (interpreted as meaning “including, but not limited to”), the compositions and methods can also “consist essentially of” or “consist of” the various components and steps, such terminology should be interpreted as defining essentially closed-member groups.

Materials

One embodiment of the invention is directed towards coated objects comprising at least one substrate and at least one coating layer. The substrate and the coating layer can directly contact each other, or there can be one or more intervening layer(s) between the substrate and the coating layer.

The substrate can generally be any material and shape. The substrate is typically a solid, but could be a gel or other semi-solid material. The substrate can be a metal, a polymer, a mineral, a ceramic, or other materials. The substrate can be flat, curved, round, or other regular or irregular shapes.

The substrate can be of any size and shape. The substrate can be very thin (one or several millimeters, for example), or can be very thick (meters or greater in thickness). Basically, any substrate can be used upon which the coating layer is applied. Specific examples of substrates include capacitors, resistors, electrodes, aircraft landing gear, aircraft flap tracks, aircraft parts, and polycarbonate discs. Other examples of substrates include watch faces, batteries, eyeglasses, lenses, razor blades, knife blades, dental instruments, medical implants, surgical instruments, stents, bone saws, kitchenware, jewelry, door handles, nails, screws, bolts, nuts, drill bits, saw blades, general household hardware, electrical insulation, boat propellers, boat propeller shafts, boat and marine products, engines, car parts, car undercarriage parts, satellites, and satellite parts.

The coating layer can completely surround the substrate, or can cover a portion of the substrate. The coating layer can be uniform or variable in thickness, although a uniform layer is frequently preferred. The coating layer thickness can be a gradient of thin to thick across all or a portion of the substrate.

The coating layer can comprise elemental carbon (C), amorphous carbon, diamond-like carbon, silicon carbide, boron carbide, boron nitride, silicon, amorphous silicon, germanium, amorphous germanium, or combinations thereof. It is presently preferred that the coating layer comprises amorphous carbon. Amorphous carbon is a stable substance that requires a considerable amount of activation energy to modify its optical properties. This feature makes amorphous carbon unaffected by typical thermal and chemical kinetic aging processes. Amorphous carbon also possesses excellent chemical resistance, and a high degree of graphitic (SP²) type carbon.

The coating layer also includes at least one oxygenated gas infused into the structure. The term “infused” refers to at least one gas that is covalently bonded, entrapped, or adsorbed into or onto the amorphous carbon or other material. The infused gas improves the adhesion of the coating layer. The infused gas also makes the coating layer deposit in a more chemically relaxed state, decreasing the chance of the coating layer cracking or peeling away from the substrate.

Upon treatment with an appropriate energy source, the treated coating layer can decompose and liberate gas. This liberated gas expands and can create a protrusion or ablation site, thereby creating a detectable optical contrast between treated sites and untreated sites. The coating layer can be infused with one gas, or can be infused with two or more different gases.

The term “oxygenated gas” refers to a gas whose molecular formula includes at least one oxygen atom. Examples of such gases include carbon monoxide (CO), carbon dioxide (CO₂), molecular oxygen (O₂), ozone (O₃), nitrogen oxides (NOₓ), sulfur oxides (SOₓ), and mixtures thereof. Oxygen is believed to increase the coating layer's volatility when heated to extreme temperatures. Oxygen is further believed to stabilize the coating layer under normal conditions, especially with regards to residual stresses in carbon films. This stabilization is believed to result as oxygen, when covalently bonded to the carbon, oxidizes the carbon to produce a very non-reactive compound. The coating layer can be infused with one oxygenated-gas, or can be infused with two or more different oxygenated gases.

The transparency (or opacity) of the coating layer can be modified by adjusting the concentration of gas used in the preparation of the coating layer. Higher concentrations of gas have been found by the instant inventors to lead to greater transparency of the coating layer. The incorporated gas can be detected and quantified using methods such as XPS. The resulting coating layer has a higher concentration of oxygenated gas than it would if prepared otherwise in the same manner but lacking the added gas during preparation.

The gas has been found to aid in ablation of the coating layer. The following is a discussion of the mechanism currently believed to enhance ablation in an optical disc prepared with a coating layer. The exact mechanism is not considered to be limiting on embodiments of the instant invention. During the write process, extreme heat generated by the write laser breaks the normally strong and stable covalent bonds between the gas and carbon atoms. The gas heating and separation process creates an explosion, expelling both the gas and the amorphous carbon from the coating layer. The gas expulsion has the combined effect of ablating the coating layer from the optical disc or permanently modifying the written portion of the coating layer to be either significantly more opaque or more transparent, depending on the system design, to a read laser than the unwritten coating layer areas. Both the written and unwritten portions of the coating layer are extremely non-reactive (unaffected by typical thermal and chemical kinetic aging processes) and optically distinct. Additionally, transforming from gas-infused to gas-less states requires significant activation energy, preventing the change from occurring through natural chemical kinetic aging.

In a similar manner, the carbon film can be ablated from other substrates using lasers or other applications of energy. Ablating of the film could be used to create a mask to guide the application of additional materials to the substrate of for other purposes that are served by patterning or removal of some of the carbon film.

The coating layer can generally be any thickness. Coating a substrate with a coating layer can confer optical absorption, improved chemical protection, and improved physical protection relative to an otherwise identical substrate lacking the coating layer. Chemical protection can include protecting the substrate against chemical attack by various agents such as solvents that dissolve or change the appearance of plastics. For example, polycarbonate is known to have limited resistance to aldehydes, and poor resistance to concentrated acids, bases, diethyl ether, esters, aliphatic hydrocarbons, aromatic hydrocarbons, benzene, halogenated hydrocarbons, ketones (such as acetone), and oxidizing agents.

For the purposes of adding optical absorption, a lower thickness limit can be about 10 nm or about 20 nm. An upper thickness limit can be determined by the energy required to modify the coating layer, and will vary depending on the material chosen. An example of an upper limit is about 100 nm. Example thicknesses are about 10 nm, about 20 nm, about 30 nm, about 40 nm, about 50 nm, about 60 nm, about 70 nm, about 80 nm, about 90 nm, about 100 nm, and ranges between any two of these values. A thickness value can be theoretically calculated as lambda/2n, where lambda is the read wavelength, and n is the index of refraction of the layer. For the purposes of adding physical protection, the coating layer thickness can be equal or higher than that for providing optical absorption. For example, an upper thickness limit can be about 100 nm, about 1,000 nm, about 10,000 nm, about 100,000 nm, or about 1,000,000 nm (1 mm). Example thicknesses are about 100 nm, about 500 nm, about 1,000 nm, about 5,000 nm, about 10,000 nm, about 50,000 nm, about 100,000 nm, about 500,000 nm, about 1,000,000 nm, and ranges between any two of these values.

Another benefit of the disclosed carbon films is the preparation of a carbon surface that has a high surface energy. This is believed to be a unique benefit of the oxygenated film. For example, the commonly employed carbon deposition process employing hydrogen (H₂) does not create a high surface energy film. This high surface energy can be used to many advantages. For example, it could provide a better adhesion to subsequently deposited films. This is in stark contrast to the poor adhesion obtained in U.S. Pat. Nos. 5,125,808 and 5,268,217, where carbon films were prepared without an infused gas, but required an “interlayer” between the carbon layer and the substrate in order to improve adhesion. Alternatively, the carbon films containing an infused gas could be used as a catalyst, allowing chemical reactions to occur at the surface interface.

The coated objects can further comprise one or more additional layers to confer additional properties to the objects. Layers can add scratch resistance, abrasion resistance, color, glimmer, reflectiveness, or a wide array of other surface properties.

In a most simple embodiment, the coated object comprises a substrate and a coating layer, wherein the coating layer facially contacts the substrate.

In an alternative embodiment, the coated object comprises a substrate, at least one intervening layer(s), and a coating layer, wherein the substrate facially contacts the intervening layer(s), and the coating layer facially contacts the intervening layer(s). A cross section of the coated object would intersect the coating layer, then the at least one intervening layer(s), and then the substrate.

Additional layers may be added to the coated object. The coated object can further comprise an ablation capture layer. The ablation capture layer can be used to retain the carbon and other materials that would be removed from the substrate or surface. An ablation capture layer can cover the coating layer to capture ablated material. Materials suitable for the ablation capture layer include aerogels, or thin metal layers. Other suitable materials include aluminum, chromium, titanium, silver, gold, platinum, rhodium, silicon, germanium, palladium, iridium, tin, indium, other metals, ceramics, SiO₂, Al₂O₃, alloys thereof, and mixtures thereof. The ablation capture layer can facially contact the coating layer. The substrate and the coating layer can facially contact each other.

Methods of Preparation

An additional embodiment of the invention relates to methods of preparing a coated object. Generally, the method can comprise providing a substrate, and applying one or more additional layers to prepare the coated object.

The various layers can be applied in various orders, depending on the particular layering desired in the coated object. The layers can all be applied on one side of the substrate, resulting in a final product having the substrate on one outer face. Alternatively, the layers can be applied onto both (or all) sides of the substrate, resulting in a final product having the substrate located such that it is not an outer face of the final product (i.e. the substrate is fully coated).

In a most simple embodiment, the method can comprise providing a substrate, and applying at least one coating layer infused with at least one oxygenated gas onto at least one face of the substrate such that the substrate and coating layer facially contact each other. The substrate can be any of the substrates discussed above. The coating layer and oxygenated gas can be any of those discussed above.

The method can further comprise exposing the substrate to a vacuum prior to the applying step.

Sputtering can be used in the applying step to apply the coating layer and other layers. Sputtering to form the coating layer can comprise providing a precursor material and at least one oxygenated gas, applying energy to the precursor material to vaporize precursor material, and depositing the vaporized precursor material and the gas onto the substrate, such that the oxygenated gas is infused in the coating layer. Additional non-oxygenated gases may be present during the sputtering, such as argon, krypton, nitrogen, helium, and neon. These gases are commonly used as an inert sputtering carrier gas.

The concentration of the oxygenated gas during sputtering can be about 0.01% (v/v) to about 25% (v/v). Specific concentrations can be about 0.01% (v/v), about 0.05% (v/v), about 0.1% (v/v), about 0.5% (v/v), about 1% (v/v), about 2% (v/v), about 3% (v/v), about 4% (v/v), about 5% (v/v), about 10% (v/v), about 15% (v/v), about 20% (v/v), about 25% (v/v), and ranges between any two of these values. These values are volume/volume with respect to the inert sputtering carrier gas (typically argon). The resulting coating layer will contain a higher concentration of infused oxygenated gas than would a coating layer prepared in otherwise the same manner but without oxygenated gas being present during the applying step.

Methods other than sputtering can be used to apply the coating layer and other layers. For example, plasma polymerization, E-beam evaporation, chemical vapor deposition, molecular beam epitaxy, and evaporation can be used.

The applying at least one coating layer infused with at least one oxygenated gas step can be performed as a single step. Alternatively, the applying step can be performed as two steps of first applying the coating layer without the infused gas, and second infusing the data layer with the gas.

In more complex embodiments, one or more additional layers can be applied to the substrate. For example, a method of preparing a coated object can comprise providing a substrate, applying at least one intervening layer(s), and applying at least one coating layer infused with at least one oxygenated gas. A cross section of the coated object would intersect the coating layer, then the at least one intervening layer(s), and then the substrate.

The method can further comprise applying an ablation capture layer such that the ablation capture layer and the coating layer facially contact each other.

The following examples are included to demonstrate preferred embodiments of the invention. It should be appreciated by those of skill in the art that the techniques disclosed in the examples which follow represent techniques discovered by the inventor(s) to function well in the practice of the invention, and thus can be considered to constitute preferred modes for its practice. However, those of skill in the art should, in light of the present disclosure, appreciate that many changes can be made in the specific embodiments which are disclosed and still obtain a like or similar result without departing from the scope of the invention.

### EXAMPLES

### Example 1

### General Method Used for Reactive Sputtering

RF sputtering was performed using a PVD 75 instrument (Kurt J. Lesker Company; Pittsburgh, Pa.). The system was configured with one RF power supply, three magnetron guns that can hold 3 inch (7.62 cm) targets, and facilities for two sputter gases. The targets were arranged in a sputter-up configuration. Shutters cover each of the three targets. Substrates were mounted on a rotating platen that can be heated up to 200° C. The rotating platen was positioned above the targets. Most of the experimentation was done with no active heating of the platen. With no active heating, the temperature of the platen gradually increases with increased sputtering time at 400 w until the temperature reaches a maximum of about 60° C.-70° C. The maximum temperature is reached after about three hours. The initial temperature in the chamber prior to sputtering was typically about 27° C. Times, targets, and sputtering sources were varied as described in the following examples.

Substrates used were typically a silicon (Si) wafer or a glass microscope slide having a UV cutoff at about 300 nm. Plasma cleaned substrates were mounted onto the platen. A portion of the silicon substrate was masked with a piece of tape having an acrylic adhesive in order to facilitate measurement of sputtering deposition rates. With the platen in place, a vacuum was applied to the sputtering chamber until the pressure is lower than 2.3×10⁻⁵ torr. Then, argon (Ar) and carbon dioxide (CO₂) in specified proportions are introduced into the chamber such that the pressure in the chamber is about 12 mtorr. The Capman pressure was maintained at 13 mtorr (the Capman pressure is an instrumental setting of the PVD 75 instrument). The plasma is then lit above the carbon graphite target (99.999%; Kurt J. Lesker Company, part number EJTCXXX503A4). The power is slowly ramped up to 400 w RF and the chamber pressure is reduced to about 2.3 mtorr (Capman pressure equals 3 mtorr), all the while maintaining the specified ratio of Ar to CO₂. Next, the shutter over the graphite target is opened and the substrate is exposed to the sputtering target for a predetermined length of time. At the end of that time, the shutter over the target closes and the power is ramped down. The substrate containing sputtered material is then removed from the instrument for analysis or further processing.

### Example 2

### General Method for AFM Thickness Measurement

Atomic force microscopy (AFM) was performed using a Veeco Dimension 3100 instrument (Veeco; Plainview, N.Y.) with the image taken in tapping mode.

The coated silicon wafer was prepared for step height measurement by AFM as follows. The tape masking a portion of the surface was removed. The surface was wet with acetone and wiped with an acetone-soaked cotton-tipped swab to remove residual adhesive and loose material at the interface between the exposed and masked portions of the wafer. The interface step height on the Si wafer was measured by AFM. A few of the films on the Si wafer were studied by XPS. The coated glass microscope slides were analyzed by UV-VIS spectroscopy.

### Example 3

### General Method for UV-VIS Measurement

UV/VIS spectroscopy of films on glass slides was performed using an Agilent 8453 UV/VIS spectrometer (Agilent; Santa Clara, Calif.). For a spectroscopy measurement, the glass slide was oriented such that the beam of light from the spectrometer passes first through the air-glass interface of the slide and then through the glass-film interface. Every scan was accompanied by a scan of plain uncoated glass slide. The absorbance spectrum of the thin film was obtained by subtracting the absorbance spectrum of the plain glass slide from the absorbance spectrum of the coated glass slide. We make the assumption that the reflectivity of the glass-air interface of the plain glass slide is the same as the reflectivity of the film-air interface on the coated glass slide, and that the reflectivity of the film-glass interface is negligible. When making a scan of a coated glass slide, the slide was positioned in such a way that the light beam of the spectrometer passes though the section of the glass slide that was 2.2 cm from the center of the platen during the sputtering deposition.

### Example 4

### General Method for Measurement of Optical Density

Optical density of a thin film was determined by dividing the UV/VIS absorbance by the film thickness. The higher the optical density of a material is at a given wavelength, the less transparent it is at that wavelength. Two samples and two measurements are used to determine optical density. The two samples are a coated, masked silicon wafer and a coated glass slide. The films on these two samples ideally are prepared simultaneously. A UV/VIS absorbance spectrum is obtained of the coated glass slide. An AFM image of the interface of the masked and exposed section of the Si wafer is obtained and a step height measurement is made to obtain the thickness of the film. Then, the absorbance values along all points of the absorbance spectrum are divided by film thickness to obtain the optical density spectrum for the film.

### Example 5

### Preparation of Disc Lacking Oxygenated-Gas Infused Coating Layer

A polycarbonate optical disk with no coatings on it was mounted on the platen in the PVD 75 instrument with the optical tracks on the disk facing the targets. A carbon graphite target was sputtered for one hour with argon as the sputter gas at a Capman pressure 3 mtorr with the magnetron power at 400 w RF. This created a carbon film on the surface of the optical disk that was about 31 nm thick. Next a layer of chromium was deposited.

### Example 6

### Preparation of Disc Containing Carbon Dioxide Infused Coating Layer

A polycarbonate optical disk with no coatings on it was mounted on the platen in the PVD 75 instrument with the optical tracks on the disk facing the targets. A carbon graphite target is sputtered for 1 hour with Ar and CO₂ as the sputter gas with the concentration of the CO₂ at a Capman pressure of 3 mtorr with the magnetron power at 400 w RF. Next, a layer of metal such as aluminum or chromium was deposited on top of the carbon film.

### Example 7

### Application of Chromium Reflective Layer

Chromium layers were applied to optical disk by sputter deposition, usually after the deposition of a carbon layer. Typically the chamber is kept under vacuum between the application carbon layer and the chromium layer. A chromium target was sputtered for 15 minutes with Ar as the sputter gas at a Capman pressure 4 mtorr with the magnetron power at 400 w RF. This created a chromium film on the surface of the optical disk that is about 138 nm thick.

### Example 8

### Measurement of Film Growth Rate by Varying Sputtering Time

AFM was used to determine the thickness of the films. As discussed, earlier, a film was masked with tape during sputtering. After sputtering, the tape was removed and the surface was cleaned. The step height was then measured by AFM. Chromium sputtered under the conditions of 400 w RF magnetron power and a Capman pressure of 4 mtorr was found to grow at a rate of 0.154 nm/s. This was determined from the slope of a calibration curve of 5 data points. Aluminum sputtered under the conditions of 400 w RF magnetron power and a Capman pressure of 3 mtorr was found to grow at a rate of 0.141 nm/s. This was determined from the slope of a calibration curve of 3 data points.

### Example 9

### Measurement of Film Growth Rate by Varying Gas Concentration

The growth rate of carbon films was found to be dependent on the percentage of carbon dioxide in the sputter gas. The experimental conditions that are constant for all experiments are 400 w RF magnetron power and Capman=3 mtorr. The amount of carbon dioxide in the process gas as a percentage of the amount of argon that has been experimented with was 0% (v/v), 1% (v/v), 2% (v/v), and 4% (v/v). The growth rates of these films are shown in the following table, and were determined by dividing the thicknesses of the films, as determined by AFM, by the sputter time.

| Percentage carbon dioxide | Thickness growth rate |
|---|---|
| 0% | 8.65 × 10⁻³ nm/s |
| 1% | 8.72 × 10⁻³ nm/s |
| 2% | 6.03 × 10⁻³ nm/s |
| 4% | 2.00 × 10⁻³ nm/s |

These growth rates clearly show that increasing carbon dioxide concentrations slows the sputtering deposition rate.

### Example 10

### Measurement of Film Optical Density (Transparency) by Varying Gas Concentration

The optical density of the carbon films was found to decrease with increasing carbon dioxide sputtering concentrations over the range 1%-4% (v/v) in the sputter gas. For this Example, films were created by sputtering carbon graphite for 4 hours at 400 w RF magnetron power and with a Capman pressure of 3 mtorr. The 650 nm optical densities of these films are shown in the following table.

| Percentage carbon dioxide | Optical density |
|---|---|
| 1% | 3.8 × 10⁻³ nm⁻¹ |
| 2% | 2.5 × 10⁻³ nm⁻¹ |
| 4% | 1.5 × 10⁻³ nm⁻¹ |

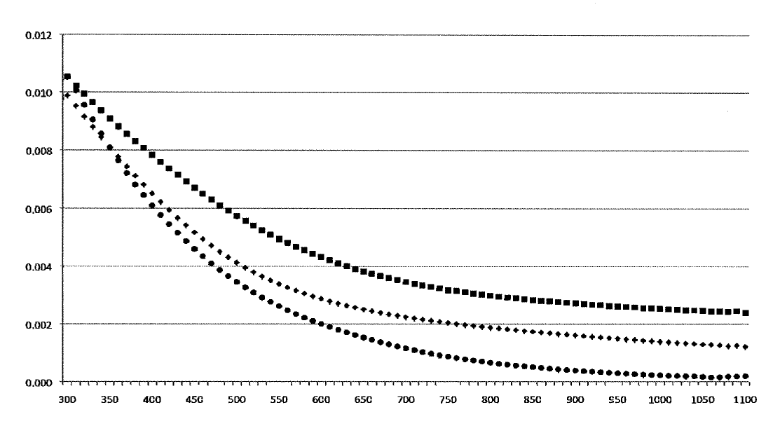

Optical densities across a spectrum from 300 nm to 1100 nm were measured, and are shown in FIG. 1. These results clearly show that increasing carbon dioxide concentrations decreased the optical density of the formed film. Stated differently, increasing carbon dioxide concentrations increased the transparency of the formed film.

### Example 11

### X-Ray Photoelectron Spectroscopy of Carbon Films Infused with Carbon Dioxide

X-ray photoelectron spectroscopy (XPS) was performed with an SSX-100 instrument (Surface Science maintained by Surface Physics; Bend, Oreg.). XPS provides elemental compositions of the upper approximately 10 nm of materials. XPS showed a steady increase in the oxygen content of the films as the percentage of carbon dioxide in the sputter gas increased. The results are shown in the following table.

| Percentage carbon dioxide | Percentage oxygen in film by XPS |
|---|---|
| 0% | 12.3% |
| 1% | 27.0% |
| 2% | 24.6% |
| 4% | 39.8% |

Additionally, a shoulder on the high energy side of the C1s narrow scan increased in size relative to the main C1s peak as the concentration of carbon dioxide in the sputter gas increased. This indicated that the amount of carbon covalently bound to oxygen increased as the percentage of carbon dioxide in the sputter gas increased.

### Example 12

### Measurement of Carbon Film Delamination

It is well known that carbon films deposited by sputtering can degrade due to internal stresses and decomposition in the atmosphere. There are distinct visible differences in appearance and properties between intact carbon films and severely degraded ones. A carbon film that has undergone severe degradation has a clouded appearance, is lighter in color and can easily be wiped away or washed off of the substrate. In contrast, an intact film is reflective and difficult to remove from the substrate.

The following experiments clearly demonstrate that infusion of carbon dioxide into a graphite film improves the stability of the film. Various films were prepared on glass microscope slides for analysis. For films created by sputtering a graphite target at 400 w with a Capman pressure of 3 mtorr, the tendency of the films to visibly degrade increases as the sputter time increases. For example, a control film created by sputtering graphite without added carbon dioxide for 1 hour did not show signs of visible degradation, but a 1.5 hour film did show signs of visible degradation. Inclusion of carbon dioxide in the sputter gas increases the time that a film can be sputtered before creating an unstable film. For example, a film created by sputtering graphite for 3 hours with 1% (v/v) carbon dioxide included in the sputter gas was not observed to degrade, but a 4 hour film did show signs of degradation. A film created by sputtering graphite for 4 hours with 2% (v/v) carbon dioxide included in the sputter gas did not show signs of degradation. These results are shown in the following table.

| % carbon dioxide | Time | Visibly degraded? |
|---|---|---|
| 0% | 1 hour | No |
| 0% | 1.5 hours | Yes |
| 1% | 3 hours | No |
| 1% | 4 hours | Yes |
| 2% | 4 hours | No |

This table shows that adding infused carbon dioxide into the films improved the mechanical stability of the films.

### Example 13

### Measurement of Carbon Film Durability

Simple tests to measure durability include immersion of the sample in boiling water for 48 hours, and a tape-pull adhesion test.

### Example 14

### Scratch Resistant Coating of Reading Glasses

A pair of glass-lens reading glasses (K-mart, Provo, Utah, i-Design™, Value Pack Designer Readers, +1.50) were mounted onto the platen of the PVD 75, such that the front of the lenses faced the cathodes. The platen was rotated during the deposition. The carbon layer was deposited as follows: ¼ inch (6.35 mm) thick graphite target (Plasmaterials, Livermore, Calif., lot# PLA489556) was sputtered; the power was 400 W DC, the capman pressure was 7 mtorr; the principal component of the sputter gas was argon; the concentration of carbon dioxide in the sputter gas was 2% (v/v); the deposition was carried out for 44:22 minutes. The film on the glasses was approximately 44 nm thick. The film increased the reflectivity of the lenses. The coated lenses were light brown in color, and functioned well as sunglasses. Darker color can easily be achieved by applying a thicker coating. The coated lenses resisted scratching by fingernail.

### Example 15

### Measurement of Carbon Film Absorption

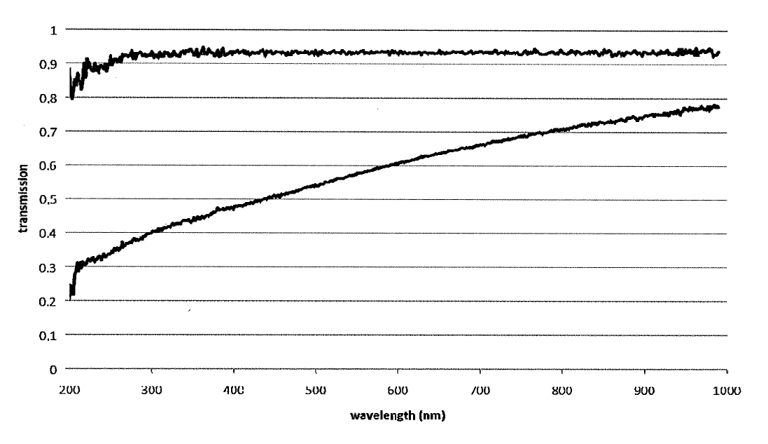

The transmission of a quartz slide, and a quartz slide coated with a carbon film infused with carbon dioxide was measured. The deposition conditions were identical to those used for coating the reading glasses in the previous Example. FIG. 2 shows that quartz (the top line) has high transmission across the wide wavelength range of 200 nm to 1000 nm. Adding the infused carbon film (bottom line) significantly reduces transmission of light through the coated object. FIG. 2 is a plot of transmission against wavelength. Transmission is particularly reduced in the ultraviolet range (wavelengths smaller than 400 nm). Ultraviolet A radiation (320-400 nm) is reduced about 48%, ultraviolet B radiation (280 nm-320 nm) is reduced about 53%, and the portion of ultraviolet C radiation (100 nm-280 nm) from 200 nm to 280 nm is reduced about 56% relative to transmission through an uncoated quartz substrate. Increasing the thickness of the infused carbon film from the relatively thin 44 nm to a higher thickness may increase these UV protection percentages.

### Example 16

### Coating of Jewelry

A clear plastic faceted bead about 1 inch (2.54 cm) in diameter (Greenbrier International, Chesapeake, Va., item #954446 92) was mounted on the platen of the PVD 75, such that the front of the lenses faced the cathodes. The deposition conditions were identical to those used for coating the reading glasses in the prior Example. The coated bead had a light brown color and, by eye, was more reflective than a control uncoated bead.

### Example 17

### Scratch Resistant Coating of Plastic Kitchenware

A clear plastic base of a butter dish, about 7 inches (17.78 cm) in length (Greenbrier International, item #858616 93) was mounted on the platen of the PVD 75, such that the bottom of the dish faced the cathodes. The deposition conditions were identical to those used for coating the reading glasses in the prior Example. The coated butter dish had a light brown color and, by eye, was more reflective than a control uncoated butter dish. The inner, uncoated face of the butter dish was easily scratched with a fingernail. The outer, coated face of the butter dish resisted scratching by fingernail.

### Example 18

### Corrosion Resistant Coating of Razor Blades

Single edge razor blades 0.009 inch (0.23 mm) thick (Famous Smith® Brand, Item #67-0238) were mounted flat on the platen, such that one face of the blades faced the cathodes. One face of the razor blades was coated using deposition conditions identical to those used for coating the reading glasses in the prior Example. The coated side of the razor blades had a uniform brown color.

Eight razor blades were submersed in a salt-water bath at 50° C. for varying periods of time. The salt-water bath was prepared by adding sodium chloride to water, in sufficient proportion to produce a 3% salt solution.

Razor blades #1 and #2 were immersed for 26 hours; #3 and #4 were immersed for 15 hours; #5 and #6 were immersed for 2 hours; #7 and #8 were the control razor blades, and were not immersed in the salt water bath.

The blades were carefully removed from the salt water bath and allowed to air dry. Pictures were then taken of the carbon-coated side and the non-coated side. It is visually obvious that the carbon coating has provided some corrosion protection, as the coated side has noticeably less rust (both red and black colored) than the uncoated side.

### Example 19

### Carbon Films Provide Protection Against Solvents

A polycarbonate disc was coated with a film of carbon infused with carbon dioxide. The coated disc did not discolor or become cloudy after rinsing with acetone. An uncoated polycarbonate disc immediately became cloudy after contact with acetone. Similarly, a polycarbonate disc coated with tellurium metal immediately became cloudy after contact with acetone. Even though the polycarbonate disc was coated (albeit with tellurium metal), it was not protected against attack by the acetone.

All of the materials and/or methods and/or processes and/or apparatus disclosed and claimed herein can be made and executed without undue experimentation in light of the present disclosure. While the compositions and methods of this invention have been described in terms of preferred embodiments, it will be apparent to those of skill in the art that variations may be applied to the materials and/or methods and/or apparatus and/or processes and in the steps or in the sequence of steps of the methods described herein without departing from the concept and scope of the invention. More specifically, it will be apparent that certain materials which are both chemically and optically related may be substituted for the materials described herein while the same or similar results would be achieved. All such similar substitutes and modifications apparent to those skilled in the art are deemed to be within the scope and concept of the invention.

What is claimed is:

1. A coated object comprising:
at least one substrate; and
at least one coating layer infused with an oxygenated gas.

2. The coated object of claim 1, wherein the substrate facially contacts the coating layer.

3. The coated object of claim 1, wherein the substrate comprises polycarbonate or glass.

4. The coated object of claim 1, wherein the substrate comprises a capacitor, a resistor, an electrode, an aircraft landing gear, an aircraft flap tracks, an aircraft part, a polycarbonate disc, watch faces, batteries, eyeglasses, lenses, razor blades, knife blades, dental instruments, medical implants, surgical instruments, stents, bone saws, kitchenware, jewelry, door handles, nails, screws, bolts, nuts, drill bits, saw blades, general household hardware, electrical insulation, boat propellers, boat propeller shafts, boat and marine products, engines, car parts, car undercarriage parts, satellites, or satellite parts.

5. The coated object of claim 1, wherein the coating layer comprises amorphous carbon, diamond-like carbon, silicon carbide, boron carbide, boron nitride, amorphous silicon, or amorphous germanium.

6. The coated object of claim 1, wherein the coating layer comprises elemental carbon (C).

7. The coated object of claim 1, wherein the coating layer comprises amorphous carbon.

8. The coated object of claim 1, wherein the oxygenated gas is carbon monoxide, carbon dioxide, molecular oxygen, ozone, nitrogen oxides, sulfur oxides, or mixtures thereof.

9. The coated object of claim 1, wherein the oxygenated gas is carbon dioxide.

10. The coated object of claim 1, wherein the oxygenated gas is covalently bonded in the coating layer.

11. A coated object comprising:
a polycarbonate or glass substrate; and
an elemental carbon coating layer infused with carbon dioxide.

12. A method for preparing a coated object, the method comprising:
providing a substrate; and
applying a coating layer infused with an oxygenated gas to prepare a coated object.

13. The method of claim 12, wherein the substrate and the coating layer facially contact each other.

14. The method of claim 12, wherein applying the coating layer comprises sputtering a precursor material and at least one oxygenated gas.

15. The method of claim 12, wherein applying the coating layer comprises sputtering a precursor material and at least one oxygenated gas, wherein the oxygenated gas is applied at a concentration of about 0.01% (v/v) to about 25% (v/v).

16. The method of claim 12, wherein the coating layer comprises amorphous carbon, diamond-like carbon, silicon carbide, boron carbide, boron nitride, amorphous silicon, or amorphous germanium.

17. The method of claim 12, wherein the coating layer comprises elemental carbon (C).

18. The method of claim 12, wherein the coating layer comprises amorphous carbon.

19. The method of claim 12, wherein the oxygenated gas is carbon monoxide, carbon dioxide, molecular oxygen, ozone, nitrogen oxides, sulfur oxides, or mixtures thereof.

20. The method of claim 12, wherein the oxygenated gas is carbon dioxide.
